(19) United States
(12) Patent Application Publication
(10) Pub. No.: US 2024/0391759 A1
(43) Pub. Date: Nov. 28, 2024

(54) MEMS COMPONENT WITH UPSIDE-DOWN CHIP

(71) Applicant: Murata Manufacturing Co., Ltd., Nagaokakyo-shi (JP)

(72) Inventors: Sami NURMI, Tuusula (FI); Joanna YLÄNEN, Espoo (FI); Susanna HURME, Vantaa (FI); Michael HALL, Vantaa (FI); Teppo SYRJÄNEN, Helsinki (FI); Anssi BLOMQVIST, Helsinki (FI); Ville-Pekka RYTKÖNEN, Klaukkala (FI)

(21) Appl. No.: 18/666,198

(22) Filed: May 16, 2024

(30) Foreign Application Priority Data
May 23, 2023 (EP) 23174731.2

(51) Int. Cl. B81B 7/00; G01C 19/5712; G01P 15/08

(52) U.S. Cl. CPC B81B 7/007; G01C 19/5712; G01P 15/08; B81B 2201/0235; B81B 2201/0242; B81B 2207/012; B81B 2207/096

(57) ABSTRACT

A device is provided that includes a MEMS chip and a housing forming an enclosure around the MEMS chip. The enclosure has a top and a bottom, the housing includes an upper unit, a lower unit and sidewalls which extend between the upper unit and the lower unit, the upper unit delimits the top of the enclosure, and the lower unit delimits the bottom of the enclosure, the lower unit or the sidewalls of the housing form an external bottom surface of the housing, the external bottom surface lies on a contacting side of the MEMS component, the housing further includes a ceramic package structure. The device includes the MEMS component and electrical connections that extend from the MEMS chip through the ceramic package structure to the contacting side of the MEMS component. The MEMS chip is mounted to the top of the enclosure.

### CROSS REFERENCE TO RELATED APPLICATIONS

This application claims priority to European Patent Application No. 23174731.2, filed May 23, 2023, the entire contents are hereby incorporated by reference in their entirety.

### TECHNICAL FIELD

The present disclosure relates to microelectromechanical (MEMS) components, and more particularly to MEMS components enclosed in a ceramic package. The present disclosure further concerns the operation of such components under mechanical stress.

### BACKGROUND

MEMS components such as accelerometers and gyroscopes typically comprise a MEMS chip and a package which forms a protective enclosure around the chip. The MEMS chip typically comprises a sealed cavity where the mobile parts of the chip are located. It also comprises electrical chip-level connections which extend from the mobile parts to the outside of the chip. Component-level electrical connections are configured to be drawn from the inside of the package to the outside. When the component is mounted on a circuit board, these component-level connections are connected to the circuit board.

FIG. 1 illustrates an conventional MEMS component. The component comprises a MEMS chip 11 and a control chip 12 inside an enclosure 18 formed by a ceramic package structure 14. The component is mounted on a printed circuit board (PCB) 16 so that the bottom surface 141 of the packaging part 14 is attached to the circuit board. The chips (11, 12) are mounted on the floor 181 of the enclosure 18. The component also comprises an electrical connection 13 which extends from the chips to a contact electrode 15 located on the bottom surface 141 of the packaging part 14. The chips are connected to the external circuit on the PCB through the contact electrode 15.

A problem with the component illustrated in FIG. 1 is that mechanical stress, illustrated by the bent shape of the PCB 16, is easily transmitted from the PCB to the floor 181 of the enclosure and from the floor to the MEMS chip 11. This can severely degrade the performance of the MEMS component since measurements will only be accurate as long as the MEMS chip is oriented correctly.

### SUMMARY OF INVENTION

An object of the present disclosure is to provide an apparatus and device for overcoming the above problem. The disclosure is based on the idea of mounting the MEMS chip on the ceiling of the enclosure.

In an exemplary aspect, a MEMS component is provided that includes a MEMS chip and a housing that forms an enclosure for the MEMS chip. In this aspect, the enclosure has a top and a bottom, the housing includes an upper unit, a lower unit and sidewalls that extend between the upper unit and the lower unit, the upper unit of the housing delimits the top of the enclosure, and the lower unit of the housing delimits the bottom of the enclosure, the lower unit or the sidewalls of the housing form an external bottom surface of the housing, and the external bottom surface lies on a contacting side of the MEMS component. Moreover, the housing further includes a ceramic package structure, and the MEMS component further comprises electrical connections that extend from the MEMS chip through the ceramic package structure to the contacting side of the MEMS component. In this aspect, the ceramic package structure forms at least the upper unit of the housing and the MEMS chip is mounted to the top of the enclosure.

In another exemplary aspect, a MEMS component is provided that includes an enclosure including an upper unit, a lower unit, a first sidewall and a second sidewall. In this aspect, the upper unit includes a first side and a second side that is opposite the first side; the lower unit includes a first side and a second side that is opposite the first side. Moreover, a MEMS chip is mounted to the first side of the upper unit; a control chip is mounted to the first side of the upper unit or the second side of the lower unit; and an electrical connection extends from the MEMS chip to an electrode located on the first side of the lower unit. The upper unit, the lower unit, and at least one of the first sidewall and the second sidewall form a ceramic package structure.

### BRIEF DESCRIPTION OF DRAWINGS

In the descriptions that follow, like parts are marked throughout the specification and drawings with the same numerals, respectively. The drawings are not necessarily drawn to scale and certain drawings may be shown in exaggerated or generalized form in the interest of clarity and conciseness. The disclosure itself, however, as well as a mode of use, further features and advances thereof, will be understood by reference to the following detailed description of illustrative implementations of the disclosure when read in conjunction with reference to the accompanying drawings, wherein:

FIG. 1 illustrates a conventional MEMS component;

FIG. 2a illustrates a MEMS component with a MEMS chip and a control chip mounted to the top of the enclosure in accordance with aspects of the present disclosure;

FIG. 2b illustrates a MEMS component with a MEMS chip mounted to the top of the enclosure and a control chip mounted to the bottom of the enclosure in accordance with aspects of the present disclosure;

FIG. 3a illustrates a MEMS component with a metallic or plastic floor structure in accordance with aspects of the present disclosure; and

FIGS. 3b-3c illustrate MEMS component where electrical connections extend to the sides of the component in accordance with aspects of the present disclosure.

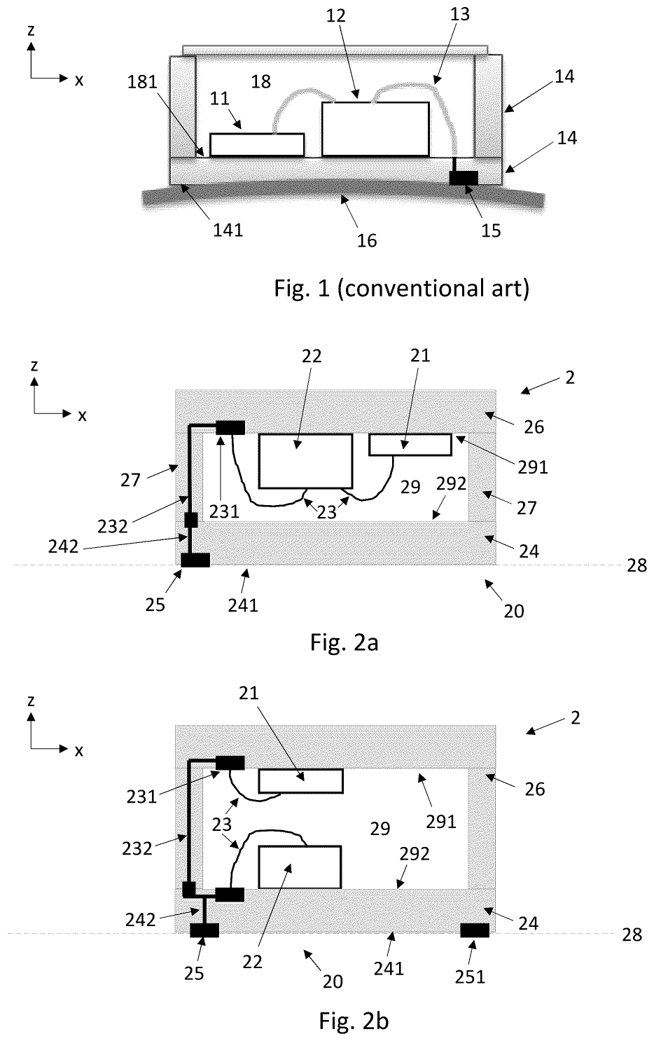

### DETAILED DESCRIPTION

This disclosure describes a MEMS component which comprises a MEMS chip and a housing which forms an enclosure around the MEMS chip. The enclosure has a top and a bottom and the housing has an upper unit, a lower unit and sidewalls which extend between the upper unit and the lower unit. The upper unit of the housing delimits the top of the enclosure, and the lower unit of the housing delimits the bottom of the enclosure.

The lower unit or the sidewalls of the housing form an external bottom surface of the housing. The external bottom surface lies on a contacting side of the component. The housing comprises a ceramic package structure. The MEMS component comprises electrical connections which extend from the MEMS chip through the ceramic package structure to the contacting side of the component. The ceramic package structure forms at least the upper unit of the housing. The MEMS chip is mounted to the top of the enclosure.

The MEMS component may be a gyroscope in any aspect presented in this disclosure. Alternatively, the MEMS component may be an accelerometer. The component may alternatively be both a gyroscope and an accelerometer: it may comprise multiple MEMS chips, some of which may be gyroscope chips and others accelerometer chips. All MEMS chips may be mounted to the top of the enclosure and connected to external contact electrodes as the Figures illustrate.

FIG. 2a illustrates a MEMS component 2 with a MEMS chip 21 and a housing which surrounds the chip 21 and forms and enclosure 29 around the chip 21. The housing comprises upper unit 26 and lower unit 24. FIG. 2a also illustrates an optional control chip 22 within the housing. The MEMS chip 21 is mounted to the top of the enclosure 29. The control chip 22 may also be mounted to the top 291 of the enclosure 29. In any aspect of this disclosure, the control chip 22 may be an ASIC (application-specific integrated circuit) chip.

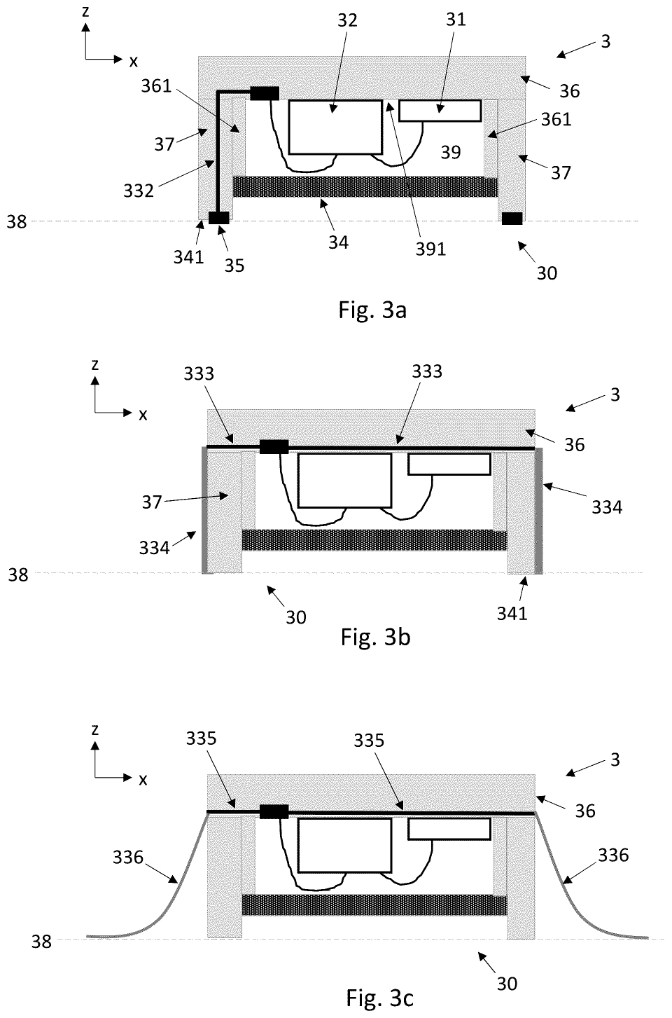

The housing also comprises sidewalls 27 which extend between the upper unit and the lower unit. The sidewalls may be an integral part of the upper unit 26 or an integral part of the lower unit 24. In general, the component 2 is assembled by mounting at least the MEMS chip 21 onto the upper unit 26 and then sealing it inside the housing by attaching the upper unit 26 to the lower unit 24. The sidewalls 27 extend between the upper unit 26 and the lower unit 24 when these units are attached to each other. The sidewalls 37 may also extend past the lower unit 34, as illustrated in FIG. 3a. In other words, the lower unit 34 may extend between the sidewalls, inside the sidewalls. The options described in this paragraph apply to all aspects of the disclosure.

The term “integral part of object A” may in this disclosure refer to a part which forms a unitary body with object A. This unitary body is a part of the housing, and it may be a body of ceramic material which has been assembled for example through a sequence of layer depositions and then heated in a ceramic firing process. The unitary body may be shaped like a cup. The MEMS chip and other components may be mounted within the unitary body. Other units and parts may then be attached to the unitary body for example by soldering or glueing, and they may seal the MEMS chip inside the enclosure 29.

The housing forms the enclosure 29 where the chips are located. The enclosure may alternatively be called a cavity. This enclosure 29 has a top 291 and a bottom 292. The MEMS chip 21 is attached to the top 291 of the enclosure 29. The control chip 22 may also be mounted to the top of the enclosure 29, as FIG. 2a illustrates. In FIGS. 2a and 2b, the lower unit 24 of the housing has an external bottom surface 241. This surface defines a contacting side 20 of the component. Electrical connections 23, 231 and 232 extend from the MEMS chip to the electrode 25 which lies on the contacting side 20. In this case the connections 23, 231 and 232 extend through the upper unit 26, the sidewalls 27 and the lower unit 24.

The terminology of this disclosure is based on the assumption that the external bottom surface 241 of the housing faces “downward”, which is the direction where the intended mounting surface will be located. In other words, when the MEMS component 2 is mounted onto a printed circuit board, the external bottom surface 241 faces the printed circuit board. The external contact electrode 25 is located on the external bottom surface 241, and it facilitates an electrical connection between the chips 21 and 22 and the underlying circuit board. The component may in practice contain multiple contacts on the bottom surface and multiple electrical paths from these contacts to the chips, but only one contact (25) and one path (23+231+232) is illustrated in FIG. 2a for simplicity.

The term “contacting side” refers in this disclosure to the side of the component where the external contact electrodes 25 of the component is configured to be electrically connected to an underlying circuit board. The contacting side 20 corresponds to the downward side, or bottom of the component, but electrical connections which extend to the contacting side do not necessarily have to be located on the bottom surface. The electrical connections are configured to be alternatively located on the sides of the component. This will be explained below with reference to FIGS. 3b and 3c.

The line 28 in FIGS. 2a-2b illustrates schematically a surface where the component may be mounted. This surface lies on the contacting side of the component. Since the MEMS chip 21 is mounted on the upper part of the housing, the MEMS chip 21 is not on the contacting side of the component. It is instead on the opposite side of the component, which is the top side.

The terms “upper”, “lower”, “top” and “bottom”, “up” and “down” are used in this disclosure as relative terms which describe the position or orientation of elements in relation to the bottom surface 241. In other words, an “upper” element is further away from the surface 241 than a “lower” element, etc. These terms do not in this disclosure refer to the orientation of the component in relation to the Earth's gravitational field. In other words, the component is configured to be oriented in any direction in relation to this field during both use and manufacturing. However, the terminology used in this disclosure assumes that when the component is mounted onto a circuit board, the bottom surface of the component faces said circuit board, while the top surface faces away from said circuit board (i.e. the top surface is further away from said circuit board than the bottom surface).

The upper unit 26 of the housing delimits the top 291 of the enclosure 29 in FIG. 2a. In other words, the upper unit 26 forms the ceiling of the enclosure. The MEMS chip 21 may be mounted directly on this ceiling, or it may be mounted to an additional mounting surface which has been attached to the ceiling. In either case, the MEMS chip 21 is mounted on the top 291 of the enclosure 29. This may be called an “upside-down position”, if we label the side of the chip which is intended to be attached to a mounting surface the “downside”, and the opposite side the “upside”. It may then be noted that the chip-centered terms “upside”/“downside” do not follow the component-centred terminology described in the previous paragraph.

The upper unit 26 may form an external top surface of the housing. The upper unit 26 comprise a ceramic package structure which may form at least the top surface of the enclosure 29. The MEMS chip 21 may be mounted directly onto the ceramic package structure. Alternatively, the component may comprise a separate mounting surface (not illustrated) which is attached to the ceramic package structure on the top 291 of the enclosure 29. The MEMS chip 21 may be mounted on this mounting surface.

The electrical connections 231 and 232 may be formed in the ceramic package structure when it is manufactured. They may for example be made of wolfram. The external contact electrode 25 may be formed in the lower unit 24, as FIGS. 2a-2b illustrate. The external contact electrode 25 may be coated for example with a Ni/Au alloy to facilitate soldering. In any aspect in this disclosure, the ceramic package structure is configured to be made of aluminium oxide, beryllium oxide or aluminium nitride.

FIG. 2a illustrates an aspect of the disclosure where the sidewalls 27 are an integral part of the upper unit 26 of the housing and a ceramic floor structure forms the lower unit 24 of the housing. The bottom of the ceramic floor structure thereby forms the external bottom surface 241 of the housing. The electrical connection 232 in which extends through the upper unit 26 and through the sidewall 27 if configured, for example, to be soldered to the corresponding electrical connection 242 in the lower unit 24 when the upper and lower units are attached to each other. This establishes electrical contact between the MEMS chip 21 and the contact electrode 25 on the external bottom surface.

More generally, a ceramic floor structure may form at least a part of the lower unit of the housing. The lower unit may have a more complex structure than FIG. 2a illustrates. Some parts of the lower unit may for example be made of ceramic materials and other parts of non-ceramic materials, such as plastics or metals. The ceramic material of the ceramic floor structure may be any of the material options listed above for the ceramic package structure. As mentioned earlier, the ceramic floor structure may form the part of the lower unit 24 where the external bottom surface 241 is located. The external contact electrode 25 may be attached to the ceramic floor structure.

The ceramic floor structure may also form the part of the lower unit 24 which delimits the bottom of the enclosure 29. In other words, the ceramic floor structure may form the bottom surface inside the enclosure 29. This is illustrated in FIGS. 2a and 2b.

FIG. 2b illustrates an alternative where the MEMS component comprises a control chip 22 inside the enclosure 20, and the control chip is 22 mounted to the bottom 292 of the enclosure 29. The electrical connections 23, 231, 232 and 242 connect the MEMS chip 21 to the control chip 22 and to the contact electrode 25. An additional contact electrode 251, which could be used for transferring an additional electrical signal between the chips and the printed circuit board, is also illustrated in FIG. 2b on the external bottom surface 241 of the housing. The control chip 22 is typically not as sensitive to mechanical stress as the MEMS chip, so the performance of the MEMS component may be the same regardless of which side of the enclosure the control chip 22 is placed on. Electrical connections which extend directly across the enclosure 29 may connect MEMS chip 21 to control chip 22. This option has not been illustrated.

FIG. 3a illustrates a MEMS component where reference numbers 30, 31, 32, 34, 35, 36, 37, 38, 39, 332 and 391 correspond to reference numbers 20, 21, 22, 24, 25, 26, 27, 28, 29, 232 and 291, respectively, in FIGS. 2a-2b. Here the lower unit 34 comprises a metallic or plastic floor structure 34 which is attached to the upper unit 36 or to the sidewalls 37 and delimits the bottom of the enclosure 39. The upper unit 36 may for example comprise a support structure 361 which is a part of the ceramic package structure and is formed around the edges of the enclosure 39. The floor structure 341 may be attached to the support structure 361. This encapsulation is configured to be made hermetic. If the floor structure 341 is metallic, then it may be attached to the ceramic support structure 361 by soldering. If the floor structure 341 is plastic, then it may be attached with glue.

The sidewalls 37 extend in FIG. 3a below the lower unit 34 and they form the external bottom surface 341 where the contact electrode 35 is located. Other arrangements are also possible. The control chip 22 may be mounted on the floor structure 34 if it is made of an insulating material. Electrical connections which extend directly across the enclosure 29 may in that case connect MEMS chip 21 to control chip 22. This option has not been illustrated.

The preceding FIGS. 2a-3a have illustrated devices where a contact electrode (25, 35) is located on the external bottom surface (241, 341) of the component. In other words, in these preceding aspects the electrical connections (232, 242, 332) are internal connections which extend through the ceramic package structure in the upper housing unit 36 and through the sidewall 37 to the external bottom surface (241, 341).

FIG. 3b illustrates an alternative configuration where the electrical connections 333 extend through the ceramic package structure which forms the upper unit 36. But no electrical connections extend through the sidewalls 37. Instead, the MEMS component comprises electrical connections 334 which extend to the contacting side 30 of the component 3 on the outer surface of the sidewalls 37. Electrical connections 334 may for example be castellations. Connections 333 and 334 are connected to each other.

FIG. 3c illustrates an alternative configuration where the electrical connections 335 extend through the ceramic package structure which forms the upper unit 36. The MEMS component here comprises electrical connections 336 which extend to the contacting side 30 of the component 3 outside of the sidewalls 37. Electrical connections 336 may for example be metallic wires. Connections 336 and 337 are coupled to each other, as FIG. 3b illustrates.

The contacting aspects illustrated in FIGS. 3a-3c can be combined with any other aspects of the disclosure presented above.

Note that the exemplary aspects described above are to facilitate the understanding of the present disclosure and is not intended to limit the present disclosure. The present disclosure can be changed or improved without departing from the spirit of the present disclosure, and the present disclosure includes equivalents thereof. That is, even a modification made by those skilled in the art to the aspects as appropriate is included in the scope of the present disclosure as long as the modification has the features of the present disclosure. In addition, respective elements provided in the aspects can be combined with each other as technically possible, and a combination thereof is also included in the scope of the present disclosure as long as the combination has the features of the present disclosure.

What is claimed:

1. A MEMS component comprising:
a MEMS chip and a housing that forms an enclosure for the MEMS chip,
wherein:
the enclosure has a top and a bottom,
the housing includes an upper unit, a lower unit and sidewalls that extend between the upper unit and the lower unit,
the upper unit of the housing delimits the top of the enclosure, and the lower unit of the housing delimits the bottom of the enclosure,
the lower unit or the sidewalls of the housing form an external bottom surface of the housing,
the external bottom surface lies on a contacting side of the MEMS component,
wherein the housing further includes a ceramic package structure,
wherein the MEMS component further comprises electrical connections that extend from the MEMS chip through the ceramic package structure to the contacting side of the MEMS component, and
wherein the ceramic package structure forms at least the upper unit of the housing and the MEMS chip is mounted to the top of the enclosure.

2. The MEMS component according to claim 1, further comprising a ceramic floor structure forms at least a part of the lower unit of the housing.

3. The MEMS component according to claim 2, wherein the ceramic floor structure forms the external bottom surface.

4. The MEMS component according to claim 3, wherein the ceramic floor structure forms the part of the lower unit that delimits the bottom of the enclosure.

5. The MEMS component according to claim 4, further comprising a control chip inside the enclosure and that is is mounted to the bottom of the enclosure.

6. The MEMS component according to claim 2, wherein the ceramic floor structure forms the part of the lower unit that delimits the bottom of the enclosure.

7. The MEMS component according to claim 1, wherein the lower unit comprises a metallic or plastic floor structure that delimits the bottom of the enclosure.

8. The MEMS component according to claim 1, wherein the MEMS component is a gyroscope.

9. The MEMS component according to claim 1, wherein the MEMS component is an accelerometer.

10. A MEMS component comprising:
an enclosure including an upper unit, a lower unit, a first sidewall and a second sidewall, wherein:
the upper unit includes a first side and a second side that is opposite the first side, and
the lower unit includes a first side and a second side that is opposite the first side;
a MEMS chip mounted to the first side of the upper unit;
a control chip mounted to the first side of the upper unit or the second side of the lower unit; and
an electrical connection that extends from the MEMS chip to an electrode located on the first side of the lower unit,
wherein the upper unit, the lower unit, and at least one of the first sidewall and the second sidewall form a ceramic package structure.

11. The MEMS component of claim 10, wherein the first sidewall and the second sidewall extend past the lower unit.

12. The MEMS component of claim 10, wherein the upper unit, the lower unit, the first sidewall, and the second sidewall are joined to create the enclosure that contains the MEMS chip and the control chip.

13. The MEMS component of claim 12, wherein the enclosure further comprises a support structure that is configured to be formed around the enclosure.

14. The MEMS component of claim 10, wherein the first side of the lower unit is mounted to a surface.

15. The MEMS component according to claim 10, wherein the lower unit includes a metallic or plastic structure.

16. The MEMS component according to claim 10, wherein the MEMS component is a gyroscope.

17. The MEMS component according to claim 10, wherein the MEMS component is an accelerometer.

18. The MEMS component according to claim 10, wherein a ceramic floor structure forms at least a portion of the lower unit.

19. The MEMS component according to claim 18, wherein the ceramic floor structure forms the first side of the lower unit.

20. The MEMS component according to claim 10, wherein the electrical connection extends from the MEMS chip to a second electrode located on the first side of the lower unit.
